(19) United States
(12) Patent Application Publication
(10) Pub. No.: US 2008/0310101 A1
(43) Pub. Date: Dec. 18, 2008

(54) Double-walled enclosure with improved cooling

(76) Inventors: Ivan Pawlenko, Holland, PA (US); Larry Samson, Langhorne, PA (US)

Correspondence Address: MENDELSOHN & ASSOCIATES, P.C., 1500 JOHN F. KENNEDY BLVD., SUITE 405, PHILADELPHIA, PA, 19102, US

(21) Appl. No.: 11/820,046

(22) Filed: Jun. 18, 2007

(51) Int. Cl. H05K 7/20; B65D 6/10

(52) U.S. Cl. 361/689; 220/62.18; 53/396

(57) ABSTRACT

In one embodiment, an enclosure for housing electrical components, such as circuit boards or the like, has one or more double-walled sides that distribute a cooling fluid to the electrical components. Each of the double-walled sides has a cavity and the cavities may be coupled together along the sides where the double-walled sides join together. A supply of pressurized fluid, such as air, is supplied to the outside wall of one double-walled side. Openings in the inner walls of the double-walled sides discharge the cooling fluid into the enclosure. The openings are positioned to provide cooling fluid where needed. Nozzles may be placed in the openings to further direct and regulate the flow of the cooling fluid into the enclosure. Baffles may be placed in the cavities to direct/deflect cooling fluid to/from the inner wall openings. The walls may be made of plastic or metal and fabricated with conventional techniques.

### FIELD OF THE INVENTION

This invention relates to enclosures or cabinets generally and, more particularly, to enclosures for electronic equipment using forced fluid cooling.

### BACKGROUND OF THE INVENTION

Typical prior art enclosures or cabinets used to encase electronic equipment, such as circuit boards, have sides that are of a single-wall construction (also known as single-layer construction) with openings in the one or more of the walls to allow the supply of cooling air to the electronics in the enclosure and venting the heated air out. Small electrically driven fans may be used to assist in the movement of air into and out of the enclosure. However, because of the structural nature of single-wall enclosures and with multiple fans assisting with the movement of air, it is difficult to direct air within the enclosure where it is needed most, e.g., at an electrical component that needs a large airflow for sufficient cooling of the component. As a consequence, the amount of airflow generated by the multiple fans to meet the minimum airflow in one area of the enclosure may be much more than needed in another area of the enclosure. Because the fans use electrical power, the efficiency of the cooling system might be poor. Moreover, the multiple fans might create more acoustic noise than is desired.

When multiple enclosures are used in a larger system, usually it is desirable to eliminate the multiple fans that are required to cool each enclosure. To cool the multiple enclosures, a single air source is typically used to simultaneously force cooling air into the multiple enclosures. But because of the aforementioned minimum airflow requirements within each enclosure, a complicated piping and damper arrangement is needed along with a common air source providing air in sufficient volume to meet the minimum airflow requirements in each enclosure. However, for all but the simplest piping and damper arrangement, such a system is complicated to design, implement, and control, and the system might provide sub-optimal cooling in one or more of the enclosures notwithstanding the sophistication of the design.

### SUMMARY OF THE INVENTION

In one embodiment of the invention, an enclosure having a plurality of sides for housing an electronic apparatus comprises at least one side of the enclosure being a double-wall structure having an inner wall and a distal outer wall forming a cavity therebetween. The double-wall structure is adapted to receive a fluid into the cavity through an opening in the outer wall, and the double-wall structure is further adapted to discharge the fluid into the enclosure.

Another embodiment is a method of making an enclosure having a plurality of sides comprises the steps of: forming at least one side of the enclosure as a double-wall structure having an inner wall, a distal outer wall, and a cavity between the inner and outer walls; and forming at least one opening in the outer wall. The double-wall structure is adapted to receive a fluid into the cavity through the opening in the outer wall, and the double-wall structure is further adapted to discharge the fluid into the enclosure.

Still another embodiment is a method of cooling an apparatus in an enclosure where at least one side of the enclosure has a double-wall structure with an inner wall and a distal outer wall forming a cavity therebetween. The method comprises the steps of: introducing a fluid into the cavity through an opening in the outer wall; and discharging the fluid into the enclosure to cool the apparatus.

### BRIEF DESCRIPTION OF THE DRAWINGS

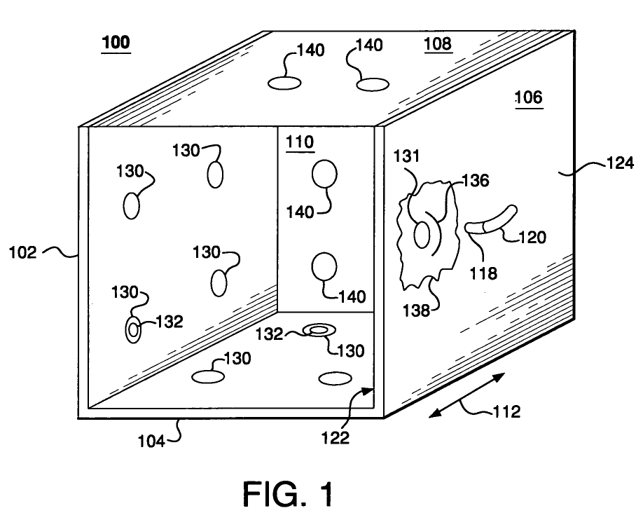

The invention will be more clearly understood from the following description of some embodiments thereof, given by way of example only, with reference to the accompanying drawings; in which FIG. 1 is an outline drawing of an enclosure according to one exemplary embodiment of the invention.

Like reference numbers are used throughout the figure to indicate like features. Individual features in the figure might not be drawn to scale.

### DETAILED DESCRIPTION

For purposes of this description and unless explicitly stated otherwise, each numerical value and range should be interpreted as being approximate as if the word “about” or “approximately” preceded the value of the value or range. Further, reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

FIG. 1 illustrates an exemplary enclosure 100 for electronic equipment, such as integrated circuits and other components on circuit boards or the like (not shown). For illustrative purposes, the enclosure 100 shown in FIG. 1 has one side removed to show the internal structure of the enclosure 100.

In the exemplary embodiment of the invention, the enclosure 100 has six sides, three of which (102, 104, 106) are double-wall structures (also known and referred to herein as double-layered structures or double-walled sides) and the remaining sides (108, 110) are single-wall structures (also known and referred to herein as single-layered or single-walled sides). The double-walled sides have an airspace or cavity (not numbered) between the inner and outer walls. It is desirable that the cavities in the double-walled sides are coupled together to allow fluid to flow through and between the cavities. Where two double-walled sides (e.g., 104, 106) are joined together at a common edge (e.g., 112), the corresponding inner walls (e.g., 122) and outer walls (e.g., 124) of the double-walled sides are desirably joined in a conventional way such that the cavities are coupled together along at least part of the length of the common edge. Further, it is preferable that the cavities are coupled along substantially the entire length of the common edge.

It is understood that the enclosure 100 may have one or more double-walled sides and that the cavities in the double-walled sides may be coupled together using other coupling techniques, such as piping. Further, while it is desirable that the enclosure 100 be fully enclosed, it is not required that all the sides are present, e.g., one or more of the sides may be eliminated. For a fully enclosed enclosure 100, doors (not shown) may replace one or more of the sides to permit access to the contents of the enclosure 100.

In the exemplary embodiment of the invention, one of the outer walls (e.g., 124) of the double-walled sides (e.g., 106) has an opening 118 with a fitting 120 therein for coupling a source of cooling fluid (not shown) for the enclosure 100. Preferably, the fluid is supplied under pressure and forced into the cavities between the inner (e.g., 122) and outer (e.g., 124) walls of the double-walled sides. Alternatively, one or more openings 118 in the outer wall (e.g., 124) with fans (not shown) placed over the openings may be used instead of the fitting 120 to supply the fluid into the cavities.

The fluid in the cavities enters the inside of the enclosure 100 through openings 130, 131 in at least one of the inner walls of the double-walled sides. It is understood that not all of the inner walls need have an opening 130, 131, e.g., there may be three inner walls but only two openings. Further, the inner walls may have an array or matrix of openings therein and plugs (not shown) placed in one or more of the openings to leave selected ones of the openings 130, 131 where needed on the inner walls. The openings 130, 131 are preferably positioned to allow the discharged cooling fluid to impinge on or near circuits or components that need cooling.

To assist in directing the cooling fluid within the enclosure, nozzles (or directing tubes) 132 may be placed in the one or more of the openings 130, 131. The nozzles may then be configured to direct the cooling fluid where the fluid is needed and, optionally, regulate the amount of cooling fluid passing therethrough.

The placement of the openings 130, 131 proximate the components in the enclosure 100 that are in need of cooling, and using the optional nozzles 132 to further direct the cooling fluid toward the components, allows for a more efficient cooling system than the above-described conventional single-walled enclosure, e.g., it is possible to cool the electronics in the enclosure 100 with a smaller cooling fluid flow rate (along with the commensurate reduction in energy needed to move the cooling fluid) than the flow rate needed with a conventional single-wall cooling enclosure. Moreover, the use of double-walled enclosures allows for a simple, single source of cooling fluid to efficiently cool multiple enclosures.

To enhance rigidity of the double-walled sides 102, 104, 106, supporting structures, such as pillars or posts (not shown), may be placed in one or more of the cavities to connect the inner and outer walls. One or more of the supporting structures may additionally operate as a baffle to directing cooling fluid to or away from openings 130, 131. The baffles in the inner walls assist in uniformly distributing the flow of cooling fluid through the double-walled sides and out of the openings 130, 131. One exemplary chevron-shaped baffle 136 is shown in cut-away 138. In this example, the baffle 136 deflects the pressurized cooling fluid supplied through the fluid supply connector 120 from directly entering opening 131 in the inner wall 122. Alternatively, a baffle may be positioned and configured to direct cooling fluid into an opening 130 in an inner wall. The baffle may have other shapes, such as a line, a semicircle, a circle, an ellipse, or combination of shapes, and the baffle need not completely span the cavity from an inner wall to an outer wall.

Exhaust holes 140 in the single-walled sides 108, 110 are provided to allow the cooling fluid to vent from the enclosure 100. Exhaust holes may also be placed in a door (if present) and in the double-walled sides. To assist in moving the cooling fluid through the enclosure 100, fans (not shown) may be placed over the exhaust holes 140 to draw or push the cooling fluid out of the enclosure 100. Further, the exhaust holes 140 may have fittings therein (not shown) to which negative pressure (with respect to the pressure within the enclosure 100) or vacuum lines (not shown) are attached to draw the coolant fluid from the enclosure 100. The enclosure 100 may be used as part of a conventional closed or sealed cooling (refrigeration) system by removing fluid from the enclosure through suction lines attached to exhaust holes 140 and recycling the fluid back to the enclosure 100 through the fitting 120.

The walls of the enclosure 100 may be made of sheet metal, plastic, or a combination of sheet metal and plastic. Sheet metal sides are joined together by conventional techniques, such as by welding. Plastic walls may be formed by a variety of known techniques, such as extrusion, and the walls bonded together to form the single- and double-walled sides of the enclosure. A well-known plastic fabrication process known as blow-molding may be used to form the one or more of the sides (double-walled and/or single-walled) in one step. Further, the plastic walls may be conductive to suppress electromagnetic interference to and from the electronics in the enclosure 100. Still further, the plastic walls may contain a UV stabilizer for outdoor applications. It is understood that the inner walls and outer walls may have different properties, e.g., the inner walls are conductive and the outer walls are UV-stabilized and of sufficient thickness to withstand physical abuse.

The cooling fluid is preferably a gas, such as air. However, with closed or sealed cooling system, it may be desirable to use another fluid such as Freon (a registered trademark of E.I. du Pont de Nemours & Company (DuPont) of Wilmington, Del.), nitrogen, or another suitable coolant material.

It will be further understood that various changes in the details, materials, and arrangements of the parts which have been described and illustrated in order to explain the nature of this invention may be made by those skilled in the art without departing from the scope of the invention as expressed in the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

1. An enclosure having a plurality of sides for housing an electronic apparatus, comprising:
at least one side of the enclosure being a double-wall structure having an inner wall and a distal outer wall forming a cavity therebetween;
wherein the double-wall structure is adapted to receive a fluid into the cavity through an opening in the outer wall, and wherein the double-wall structure is further adapted to discharge the fluid into the enclosure.

2. The enclosure of claim 1, wherein at least two sides of the enclosure are double-wall structures, each of the double-wall structures having a cavity therein, and wherein the cavities of the double-wall structures are coupled together.

3. The enclosure of claim 2, wherein the two double-wall structures are joined together along a common edge and the cavities therein are coupled together along the common edge.

4. The enclosure of claim 1, wherein the inner wall of the double-wall structure has at least one opening therein for discharging the fluid from the cavity into the enclosure.

5. The enclosure of claim 1, further comprising at least one baffle disposed in the cavity.

6. The enclosure of claim 5, wherein the inner wall has at least one opening, and wherein the baffle assists in directing the fluid in the cavity out of the least one opening.

7. The enclosure of claim 1, wherein the inner wall has at least one opening with a nozzle inserted therein.

8. The enclosure of claim 1, wherein the opening in the outer wall has a fitting therein adapted for coupling to a pressurized source of the fluid.

9. The enclosure of claim 1, wherein at least one side of the enclosure has at least one exhaust opening therein for venting the fluid from the enclosure.

10. The enclosure of claim 9, wherein the exhaust opening has a fitting therein adapted for coupling to a source of negative pressure to draw the fluid from the enclosure.

11. The enclosure of claim 1, wherein the fluid is air.

12. The enclosure of claim 1, wherein at least three contiguous sides of the enclosure are double-wall structures and each double-wall structure has a cavity therein; wherein adjacent double-wall structures are joined together along a common edge and the cavities in the adjacent double-wall structures are coupled together along the common edge; wherein the inner walls of the three double-wall structures together have a plurality of openings, at least one of the openings having a nozzle therein; wherein one of the outer walls of the three double-wall structures has the opening therein, and the opening in the outer wall has a fitting therein adapted for coupling to a pressurized source of the fluid; and wherein the double-wall structures are adapted to receive the pressurized fluid into the fitting and pass the fluid through the cavities and into the enclosure through the inner wall openings and through the nozzle.

13. The enclosure of claim 1, further comprising at least one plug; wherein the inner wall of the double-wall structure has a plurality of openings therein for discharging the fluid from the cavity into the enclosure, and wherein the plug is placed in one of the plurality of openings.

14. A method of making an enclosure having a plurality of sides, comprising the steps of:
forming at least one side of the enclosure as a double-wall structure having an inner wall, a distal outer wall, and a cavity between the inner and outer walls; and
forming at least one opening in the outer wall;
wherein the double-wall structure is adapted to receive a fluid into the cavity through the opening in the outer wall, and wherein the double-wall structure is further adapted to discharge the fluid into the enclosure.

15. The method of claim 14, further comprising the step of:
forming in at least one side of the enclosure at least one exhaust opening.

16. The method of claim 14, further comprising the steps of:
forming at least one additional side of the enclosure as a double-wall structure having a cavity therein; and
forming at least one opening in at least one of the inner walls of the double-wall structures;
wherein for each double-wall structure joined to another double-wall structure along a common edge, the cavities of the joined double-wall structures are coupled together along the common edge.

17. The method of claim 14, further comprising the steps of:
forming an opening in the inner wall; and
inserting a nozzle into the opening in the inner wall.

18. The method of claim 14, further comprising the step of:
forming at least one baffle in the cavity.

19. The method of claim 14, wherein the walls are plastic and formed by blow-molding.

20. A method of cooling an apparatus in an enclosure where at least one side of the enclosure has a double-wall structure with an inner wall and a distal outer wall forming a cavity therebetween, comprising the steps of:
introducing a fluid into the cavity through an opening in the outer wall; and
discharging the fluid into the enclosure to cool the apparatus.

21. The method of claim 20, wherein the inner wall of the double-wall structure has at least one opening therein, and wherein the fluid is discharged through the at least one opening.

22. The method of claim 21, wherein the at least one opening has a nozzle inserted therein, further comprising the step of directing the discharged fluid toward the apparatus using the nozzle.

23. The method of claim 20, wherein at least two sides of the enclosure are double-wall structures, each of the double-wall structures having a cavity therein, wherein the two double-wall structures are joined together along a common edge and the cavities therein are coupled together along the common edge, wherein the inner walls of the structures having openings therein, and wherein the fluid is discharged into the enclosure through the openings.
